(19) United States
(12) Patent Application Publication
(10) Pub. No.: US 2010/0029087 A1
(43) Pub. Date: Feb. 4, 2010

(54) APPARATUS AND METHOD FOR ETCHING SEMICONDUCTOR WAFER

(75) Inventor: Kenji OKITA, Saga (JP)

Correspondence Address: GREENBLUM & BERNSTEIN, P.L.C., 1950 ROLAND CLARKE PLACE, RESTON, VA, 20191, US

(73) Assignee: SUMCO CORPORATION, Tokyo (JP)

(21) Appl. No.: 12/511,491

(22) Filed: Jul. 29, 2009

(30) Foreign Application Priority Data
Jul. 31, 2008 (JP) 2008-198971

(51) Int. Cl. H01L 21/306; C23F 1/08

(52) U.S. Cl. 438/745; 156/345.23; 156/345.18; 257/E21.219

(57) ABSTRACT

An apparatus for etching a semiconductor wafer of the present invention includes a cylindrical inner bath 1 which stores an etchant, a blow-off nozzle 13 which supplies the etchant from a middle part of a bottom surface 7 of the inner bath 1 toward a middle part of a liquid surface of the etchant, a Bernoulli chuck 41 which holds one surface of the semiconductor wafer W in a noncontact manner, and raising and lowering means 51 which is capable of descending, while keeping the semiconductor wafer W horizontal, to a set height at which the other surface of the semiconductor wafer W to be etched comes into contact with the liquid surface. The inner bath 1 is formed in such a manner that the outside diameter of the inner bath 1 is not more than the outside diameter of the semiconductor wafer W. As a result of this, it is possible to prevent the splash of the etchant when one surface of the wafer is etched, with the wafer held by use of the Bernoulli chuck.

### BACKGROUND OF THE INVENTION

1. Field of the Invention

The present invention relates to an apparatus and method for etching a semiconductor wafer.

2. Description of the Related Art

In the manufacturing process of semiconductor wafer, high-temperature heat treatment (annealing) is repeatedly performed during the steps of, for example, oxidation, diffusion, film formation and the like. In the manufacturing process of, for example, SIMOX wafers, heat treatment is performed in a high-temperature oxidizing atmosphere, with the silicon wafer held by a heat treatment jig made of silicon or made of silicon carbide (SiC).

Incidentally, when heat treatment is repeated in the oxidizing atmosphere, an oxide film grows on the surface of the heat treatment jig and part of the oxide film may be transferred to a holding surface (hereinafter referred to as the back surface) of a semiconductor wafer which comes into contact with the heat treatment jig.

An oxide (i.e. the part of the oxide film) which has been transferred to the back surface of the semiconductor wafer (hereinafter referred to as “wafer”) in this manner can hardly be removed in the subsequent cleaning step. Irregularities on the back surface due to such transfer of the oxide, for example, cause defocusing to occur during exposure in the photolithography step in the process of device manufacturing and cause the oxide which has been transferred to exfoliate from the wafer back surface, thereby adhering to other wafers, both becoming factors responsible for a decrease in yield.

In order to solve such problems with the back surface side of a wafer, conventionally, there has been introduced a process which involves improving the surface condition by etching the back surface of the wafer after heat treatment. Specifically, for example, there has been proposed a technique which involves filling an etchant in a cylindrical etching bath whose upper part opens, causing the liquid surface to swell by supplying the etchant below the liquid surface of the etchant, and bringing the swollen liquid surface and the back surface of a semiconductor wafer into contact with each other to widen the contact region by use of the surface tension of the etchant, whereby the whole back surface of the wafer is etched (refer to JP 2003-17464 A1).

JP 2003-17464 A1 describes preventing the deterioration of the surface by forming a cylindrical wall of the etching bath to be larger than the outside diameter of a wafer, directing the vapor of an etchant which has vaporized from the liquid surface around the wafer to an outer circumferential portion of the wafer thereby to etch part of the outer circumferential portion, and at the same time supplying an inert gas annularly from the front surface side of the wafer in the outer circumferential direction thereby to protect the surface of the wafer from the vapor.

### Patent Document 1: JP 2003-17464 A1

### SUMMARY OF THE INVENTION

Incidentally, JP 2003-17464 A1 describes, as holding means of the wafer, holding the wafer by sucking the front surface side of the wafer by use of a vacuum chuck and the like. However, if such holding means is used, particles are likely to adhere to the front surface side of the wafer. The particles which have adhered to the front surface side may not be completely removed in a usual cleaning step. Such a situation must be avoided as much as possible from the standpoints of the productivity of products, yield, quality reliability and the like.

Therefore, as the holding means of the wafer during etching, the use of a Bernoulli chuck is being studied. This Bernoulli chuck can lift up the wafer without causing the wafer to contact with the chuck surface because a lift force based on the Bernoulli's theorem acts on the wafer. For this reason, compared to conventional contact type holding means, it is possible to suppress the adhesion of particles to the front surface side of the wafer.

However, in this Bernoulli chuck, chattering associated with the flow of a suction gas is likely to occur in the wafer. If such vibrations of the wafer propagate to the liquid surface around the wafer within an etching bath as described in JP 2003-17464 A1, the vibrations may splash the etchant. If the etchant is splashed, the etchant will adhere to the non-etched region of the wafer and might deteriorate the surface.

The present invention has as its object to prevent the splash of the etchant when one surface of the wafer is etched, with the wafer held by use of the Bernoulli chuck.

To solve the above-described problem, an apparatus for etching a semiconductor wafer of the present invention includes a cylindrical etching bath which stores an etchant, a supply port which supplies the etchant from a middle part of a bottom surface of the etching bath toward a middle part of a liquid surface of the etchant, a Bernoulli chuck which holds one surface of the semiconductor wafer in a noncontact manner, and raising and lowering means which is capable of descending, while keeping the semiconductor wafer horizontal, to a set height at which the other surface of the semiconductor wafer to be etched comes into contact with the liquid surface. In this apparatus for etching a semiconductor wafer, the etching bath is formed in such a manner that the outside diameter of the etching bath is not more than the outside diameter of the semiconductor wafer.

According to the present invention, the outside diameter of the etching bath is set to be not more than the outside diameter of the semiconductor wafer and, therefore, during etching, the whole liquid surface of the etching bath is covered with the semiconductor wafer. For this reason, even when vibrations occur in the semiconductor wafer held by the Bernoulli chuck, the effect of the vibrations on the liquid surface is small and, therefore, the splash of the etchant can be prevented. Also, the evaporation surface of the etchant is limited to a portion of the liquid surface of the etchant overflowing from a gap between the etching bath and the surface of the wafer to be etched and, therefore, it is possible to suppress the evaporation of the etchant. Therefore, it is possible to prevent the non-etched region of the semiconductor wafer from deteriorating due to the splash of the etchant and the evaporation of the etchant. The outside diameter of the etching bath may be equal to the outside diameter of the semiconductor wafer or may be smaller than the outside diameter of the semiconductor wafer. However, in order to reduce the effect of the splash of the etchant and the vapor of the etchant to a smaller extent, it is more preferred that the outside diameter of the etching bath be smaller than the outside diameter of the semiconductor wafer.

In this case, the Bernoulli chuck is provided with an annular gas supply port which sends gas to the side of an outer circumferential portion of one surface of the semiconductor wafer. Because of this, it is possible to prevent the vapor of the etchant from intruding on the side of one surface of the semiconductor wafer and, therefore, it is possible to more reliably prevent the deterioration of the non-etched region of the semiconductor wafer.

The apparatus for etching a semiconductor wafer of the present invention also includes a storage bath which stores the etchant which overflows the etching bath, and circulation means which extracts the etchant in the storage bath by a pump and returns the etchant to the supply port. By using the etchant in a circulating manner like this, it is possible to continuously maintain the liquid surface in the etching bath at a certain height and it is possible to reduce the process cost by reducing etchant waste.

The etching bath has an inner wall surface which spreads in the form of an inverted cone from a circumference of the supply port toward an upper end of the etching bath. Because of this, for example, the etchant supplied from the supply port into the etching bath flows so as to spread from the center in the radial direction along the inner surface wall and, therefore, the stagnation of the etchant in the bath is suppressed, making it possible to form a flow of the liquid without turbulence. As a result of this, when the semiconductor wafer has come into contact with the etchant, the region in which the etchant and the semiconductor wafer are in contact with each other expands smoothly in the circumferential direction. For this reason, the outer circumferential portion of the semiconductor wafer is uniformly in contact with the liquid surface in the circumferential direction and hence it is possible to suppress nonuniform etching.

In an etching method for etching a semiconductor wafer by use of an etching apparatus in which the outside diameter of an etching bath is set, at least either a set height of the surface of the semiconductor wafer to be etched or a supply amount of the etchant supplied from the supply port is adjusted and the etchant is brought into contact with a prescribed position of an outer circumferential portion of the semiconductor wafer. That is, a set height of the surface of the semiconductor wafer to be etched and a supply amount of the etchant supplied from the supply port are adjusted, whereby the surface tension acting on the etchant passing between the top end surface of the etching bath and the surface of the semiconductor wafer to be etched changes. The position of the liquid surface depends on the magnitude of the surface tension. Therefore, by appropriately adjusting a set height of the surface of the semiconductor wafer to be etched and a supply amount of the etchant supplied from the supply port, it becomes possible to adjust the region in which the etchant comes into contact with the semiconductor wafer within an appropriate range.

According to the present invention, it is possible to prevent the splash of an etchant when one surface of a wafer is etched, with the wafer held by use of a Bernoulli chuck.

### BRIEF DESCRIPTION OF THE DRAWINGS

FIG. 1 is a longitudinal sectional view showing the general arrangement in an embodiment of an etching apparatus to which the present invention is applied;

FIG. 2 is a perspective view showing the appearance of a Bernoulli chuck in the embodiment of an etching apparatus to which the present invention is applied;

FIG. 3 is an enlarged perspective view of a wafer holding portion of a Bernoulli chuck in the embodiment of an etching apparatus to which the present invention is applied;

FIGS. 4(a) to 4(c) are diagrams to explain the operation in the embodiment of an etching apparatus to which the present invention is applied; and

FIG. 5 is a longitudinal sectional view showing the general arrangement in another embodiment of an etching apparatus to which the present invention is applied.

### DETAILED DESCRIPTION OF THE INVENTION

Hereinafter, embodiments of an etching apparatus for a semiconductor wafer to which the present invention is applied will be described with reference to the drawings.

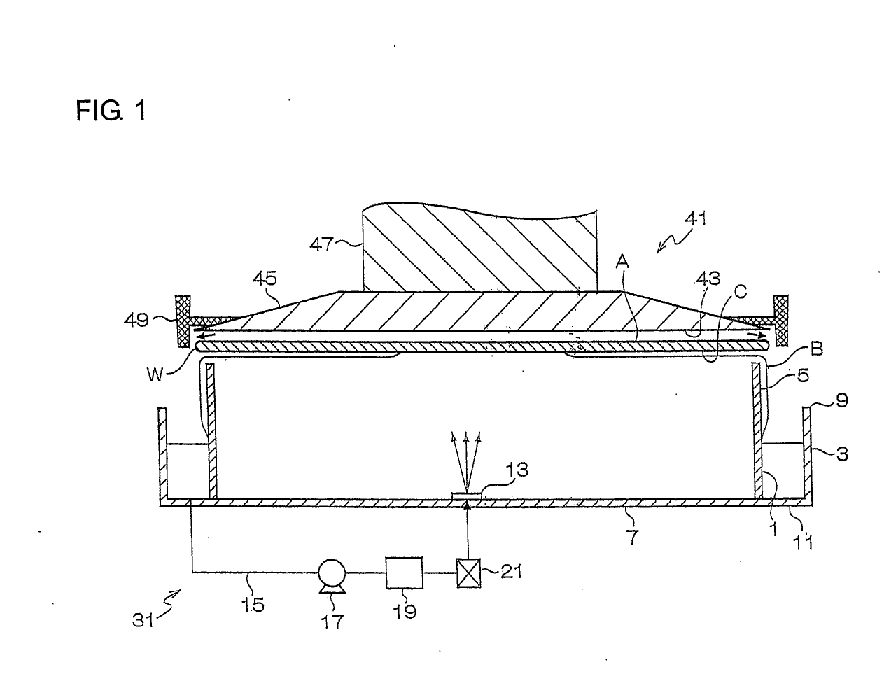

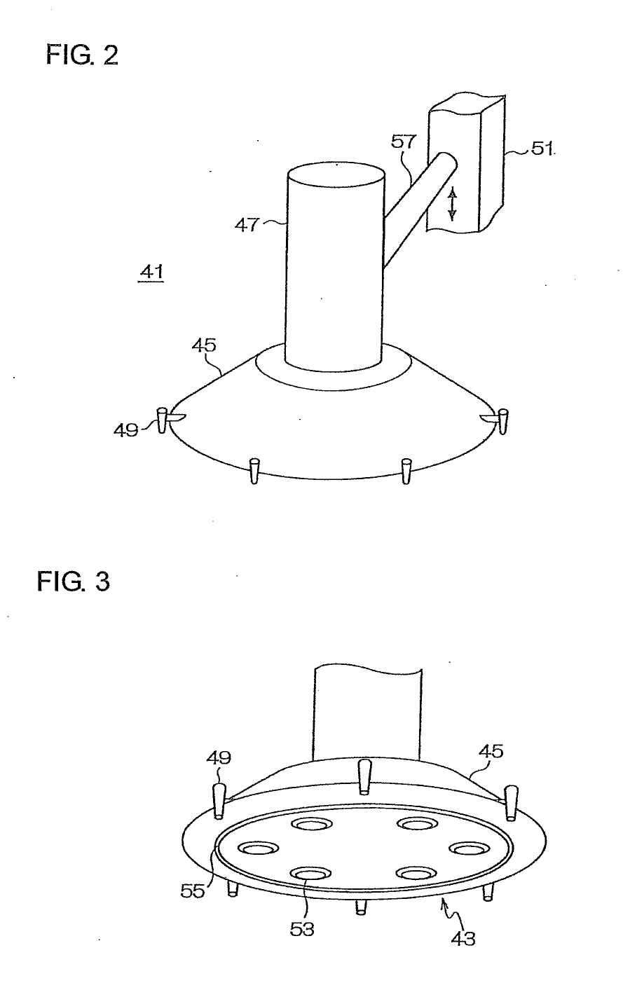

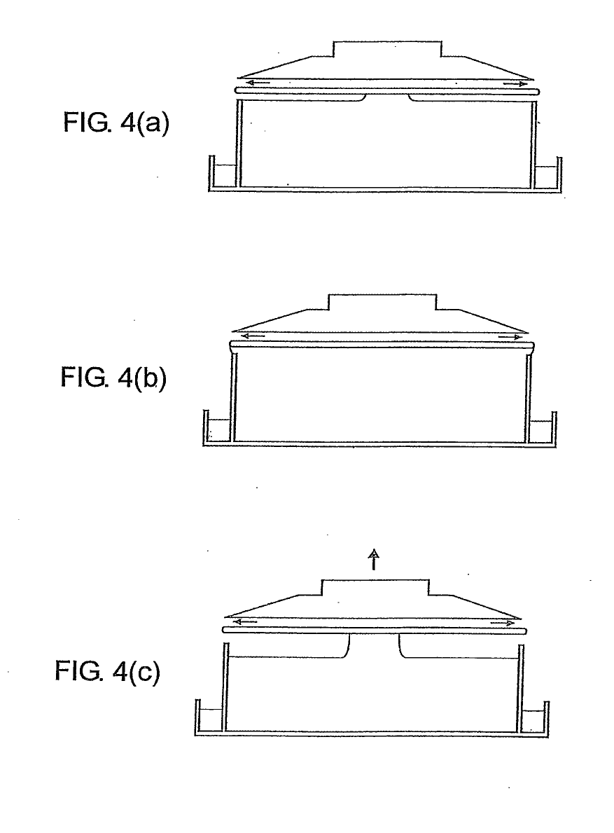

FIG. 1 is a longitudinal sectional view showing the general arrangement of an etching apparatus to which the present invention is applied. FIG. 2 is a perspective view showing the appearance of a Bernoulli chuck of the etching apparatus to which the present invention is applied. FIG. 3 is an enlarged perspective view of a wafer holding portion of the Bernoulli chuck of the etching apparatus to which the present invention is applied. FIGS. 4(a) to 4(c) are diagrams to explain the operation of the etching apparatus to which the present invention is applied.

In this embodiment, semiconductor wafers can include a silicon wafer, a gallium arsenide wafer and the like. However, a SIMOX wafer after heat treatment (hereinafter, abbreviated as “wafer”) will be described here. In the outer circumferential portion of the wafer, a circumferential chamfered portion is formed each on the front surface side and the back surface side. The whole back surface of the wafer W and the back surface side (the chamfered portion) of the outer circumferential portion of the wafer W are regarded as the etching range of the wafer W. An oxide film and the like may or may not be applied on one surface of the wafer. Although etchants can include HF (hydrofluoric acid), HF: NH₄F and the like, the etchant is not limited to these examples.

As shown in FIGS. 1 and 2, the etching apparatus of this embodiment is configured by including a cylindrical inner bath 1, a cylindrical outer bath 3 which is formed to surround this inner bath 1, circulation means 31 which circulates an etchant between the inner bath 1 and the outer bath 3, a Bernoulli chuck 41 which holds a semiconductor wafer W in a noncontact manner while keeping the wafer W horizontal, and raising and lowering means 51 which supports the Bernoulli chuck 41 so as to be able to ascend and descend in the height direction.

The inner bath 1 is composed of a cylindrical wall 5 and a bottom surface 7, and the outer bath 3 is composed of a cylindrical wall 9, whose inside diameter is larger than the outside diameter of the cylindrical wall 5, and a bottom surface 11. That is, the inner bath 1 and the outer bath 3 are coaxially arranged and are constructed to be partitioned by the cylindrical wall 5 from each other. The outside diameter of the cylindrical wall 5 of the inner bath 1 is set to be the same as the outside diameter of the wafer W or to be smaller than this. The outside diameter of the wafer W means a maximum diameter of the wafer W.

The etchant overflowing the inner bath 1 can be stored in a space formed by being surrounded by the cylindrical wall 5 of the inner bath 1, the cylindrical wall 9 of the outer bath 3 and the bottom surface 11. A blow-off nozzle 13 which blows off the etchant directly upward is provided in a middle part of the bottom surface 7 of the inner bath 1.

Next, the construction of the circulation means 31 will be described. The circulation means 31 is composed of a circulation pipe 15, one end of which is connected to the bottom surface 11 of the outer bath 3 and the other end of which is connected to the blow-off nozzle 13, and a circulation pump 17, a temperature adjusting device 19, and a filter 21, which are arranged in this circulation pipe 15 in order from the side of one end (the upstream side). The circulation pump 17 is adapted to ensure that the discharge rate of the etchant is controlled. The temperature adjusting device 19 is constructed so that, for example, heat exchange is performed between the pipe through which the etchant flows and heating means, and is adapted to ensure that, for example, the temperature of the heating means is controlled on the basis of detected temperature of the etchant.

Next, the construction of the Bernoulli chuck 41 will be described. As shown in FIGS. 1 and 2, the Bernoulli chuck 41 is constructed to have a wafer holding portion 45, which is formed to diverge in the form of a cone in the direction toward the bottom surface opposed to a front surface A of the wafer W (a chucking surface 43), and a supporting portion 47 connected to an upper end surface of the wafer holding portion 45. A plurality of guides 49 which guide the wafer are provided on an outer circumferential surface of the wafer holding portion 45. An arm 57 of the raising and lowering means 51 is connected to the supporting portion 47.

As shown in FIG. 3, a plurality of (for example, six) suction nitrogen delivery ports 53 which deliver nitrogen gas are formed in a circumferential direction on the chucking surface 43 of the wafer holding portion 45, and a nitrogen delivery groove 55 which delivers surface protection nitrogen gas is annularly formed so as to surround these nitrogen delivery ports 53.

Next, the operation of the etching apparatus thus constructed will be described. With the etchant stored within the inner bath 1, the etchant is blown off directly upward from the blow-off nozzle 13 by the action of the circulation pump 17. As a result of this, a middle part of a liquid surface B swells in the etchant stored within the inner bath 1. At this time, the etchant overflowing from within the inner bath 1 passes over the upper end surface of the cylindrical wall 5 and flows down into the outer bath 3.

The etchant stored within the outer bath 3 is guided into the circulation pump 17 through the circulation pipe 15. The etchant discharged from the circulation pump 17 passes through the temperature adjusting device 19 and is heated to prescribed temperature. Subsequently, the etchant is filtered by the filter 21 and is then supplied in a circulating manner to the inside of the inner bath 1 via the blow-off nozzle 13.

On the other hand, for the Bernoulli chuck 41, nitrogen gas is blown off from the nitrogen delivery port 53 of the wafer holding portion 45, whereby a lift force acts on the wafer W. As a result, the wafer W sucked onto the chucking surface 43 is held by the wafer holding portion 45, with the front surface A being in noncontact with the chucking surface 43. At this time, the wafer W held by the wafer holding portion 45 is in such a condition that a back surface C is opposed to the liquid surface B of the etching apparatus at a prescribed interval from the liquid surface B.

Next, the raising and lowering means 51 causes the wafer W held by the Bernoulli chuck 41 to descend horizontally to a prescribed height at which the back surface C of the wafer W can be brought into contact with the swollen part of the liquid surface B of the inner bath 1. As a result of this, the swollen part of the middle of the liquid surface B comes into contact with the middle part of the back surface C of the wafer W held horizontally above the liquid surface (FIG. 4(a)).

Subsequently, due to the surface tension of the etchant acting on the back surface C of the wafer W, the contact region of the etchant expands uniformly from the middle part of the wafer W in the outer circumferential direction and is held in such a condition that the contact region of the etchant is in contact with the back surface side (the chamfered portion) of the outer circumferential portion of the wafer W (FIG. 4(b)).

The etching proceeds in this manner, whereby an oxide and a surface oxide film adhering to the back surface C of the wafer W during heat treatment are removed by the erosion action of the etchant.

Incidentally, in this embodiment, the outside diameter of the cylindrical wall 5 is set to be not more than the outside diameter of the wafer W and, therefore, the etchant overflowing the inner bath 1 passes through a gap between the back surface C of the wafer W and the upper end surface of the cylindrical wall 5. The surface tension acts on the etchant passing through this gap in relation to the upper end surface of the cylindrical wall 5 and the back surface C of the wafer W respectively, and the region in which the etchant comes into contact with the wafer W depends on the surface tension in these portions. This surface tension acting on the etchant changes depending on the size of the gap between the upper end surface of the cylindrical wall 5 and the back surface C of the wafer W, as well as the flow rate of the etchant passing through this gap.

Therefore, during etching, it becomes possible to control the region in which the etchant comes into contact with the wafer W by adjusting at least either the height position of the back surface C of the wafer W relative to the upper end surface of the cylindrical wall 5 or the discharge rate of the circulation pump 17. In this case, the height position of the back surface C of the wafer W can be adjusted by use of the raising and lowering means 51 and the discharge rate of the circulation pump 17 can be adjusted, for example, by issuing from the outside instructions for the number of revolutions to the circulation pump 17.

For the speed of the wafer W descending while the wafer W moves to a prescribed position after coming into contact with the etchant, for example, adjustment is made in addition to the adjustment of the flow rate of the etchant, whereby it is possible to control the speed of expansion of the region in which the etchant and the wafer W come into contact with each other. As a result of this, it is possible to prevent the etchant from intruding on the non-etched region of the wafer W (the front surface side of the outer circumferential portion (the chamfered portion) and the front surface A).

During etching, the wafer W held by the Bernoulli chuck 41 may generate vibrations under the influence of the flow of nitrogen gas blown off from the nitrogen delivery port 53. However, in this embodiment, the outside diameter of the cylindrical wall 5 is set to be not more than the outside diameter of the wafer W and the whole liquid surface within the inner bath 1 is covered with the back surface C of the wafer W and, therefore, the splash of the etchant will not occur even when such vibrations of the wafer W propagate to the liquid surface B. Therefore, also in such a case, it is possible to prevent the deterioration of the non-etched region of the wafer W due to the scattering of the etchant.

Next, when etching is finished, the raising and lowering means 51 causes the wafer W to ascend and causes the back surface C to depart from the liquid surface B.

At this time, due to the surface tension related to the back surface C of the wafer W, the swollen portion of the middle of the liquid surface comes to a condition in which the swollen portion is raised to a prescribed height (FIG. 4(c)) and the liquid surface descends a little. Gentle swinging occurs in the liquid surface because this raised liquid surface falls soon from the back surface C of the wafer W by gravity. However, even in such a case, it is possible to prevent the deterioration of the non-etched region of the wafer W due to the splash of the liquid surface, because the outside diameter of the cylindrical wall 5 is not more than the outside diameter of the wafer W.

According to this embodiment, the evaporation surface of the etchant is limited to the portion where the etchant overflows through the gap between the upper end surface of the cylindrical wall 5 and the back surface C of the wafer W, with the exception of the etchant stored within the outer bath 3 and, therefore, it is possible to suppress the evaporation of the etchant. As a result of this, it is possible to prevent the deterioration of the non-etched region of the wafer W due to etching components in the vapor produced by the evaporation of the etchant.

Furthermore, according to this embodiment, the nitrogen gas blown off from the nitrogen delivery groove 55 of the Bernoulli chuck 41 flows annularly to the side of the outer circumferential portion along the surface of the wafer W, and this nitrogen gas flows on the front surface side of the outer circumferential portion. Because the intrusion of the vapor of the etchant can be prevented by covering the non-etched region of the wafer W with nitrogen gas in this manner, it is possible to more reliably prevent the deterioration of the non-etched region of the wafer W.

According to this embodiment, because while the wafer W is brought into contact with the etchant, the region of the contact of the wafer W with the etchant expands from the middle of the wafer W in the outer circumferential direction and also during etching, because the etchant flows in the outer circumferential direction along the back surface C of the wafer W, nonuniform etching due to bubbles will not occur on the back surface C of the wafer W.

According to conventional etching methods, the vapor of the etchant has been positively used in order to etch the outer circumferential portion of the back surface C side of the wafer W. In this embodiment, however, the etchant in the liquid state is brought into contact with the outer circumferential portion and, therefore, it is possible to make the boundary between the etched region and the non-etched region clearer than in the etching by use of vapor.

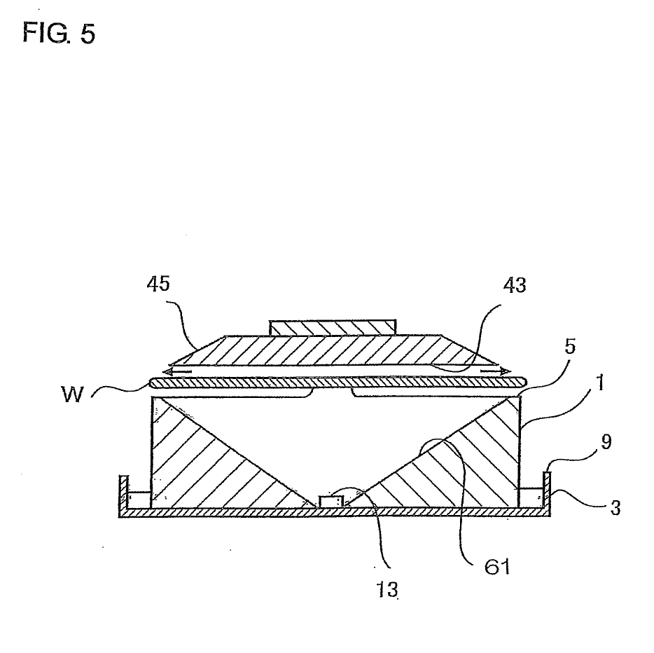

Next, a description will be given of another embodiment of an apparatus for etching a semiconductor wafer to which the present invention is applied. FIG. 5 is a longitudinal sectional view showing the general arrangement of the etching apparatus of this embodiment.

As shown in FIG. 5, the construction of the etching apparatus of this embodiment differs from the construction of the etching apparatus of FIG. 1 in that an inner wall surface 61 of an inner bath 1 is formed to spread in the form of an inverted cone from a bottom portion thereof near a blow-off nozzle 13 toward an upper end thereof.

According to the etching apparatus of this embodiment, an etchant supplied from the blow-off nozzle 13 into the inner bath 1 flows so as to spread from the center in the radial direction along the inner wall surface 61 as a whole. Therefore, within the inner bath 1, local stagnation of the etchant is suppressed and it is possible to form a flow without turbulence. As a result of this, while the wafer W is brought into contact with the etchant, the region of the contact of the wafer W with the etchant expands uniformly and smoothly from the middle of the wafer W in the outer circumferential direction. Therefore, the outer circumferential portion of the wafer W is uniformly in contact with the liquid surface B in the circumferential direction and it is possible to suppress nonuniform etching. In addition, on the back surface of the wafer W it becomes possible to perform etching without the accumulation of bubbles.

What is claimed is:

1. An apparatus for etching a semiconductor wafer, comprising:
a cylindrical etching bath which stores an etchant;
a supply port which supplies the etchant from a middle part of a bottom surface of the etching bath toward a middle part of a liquid surface of the etchant;
a Bernoulli chuck which holds one surface of the semiconductor wafer in a noncontact manner; and
raising and lowering means which is capable of descending, while keeping the semiconductor wafer horizontal, to a set height at which the other surface of the semiconductor wafer to be etched comes into contact with the liquid surface,
wherein the etching bath is formed in such a manner that the outside diameter of the etching bath is not more than the outside diameter of the semiconductor wafer.

2. The apparatus for etching a semiconductor wafer according to claim 1, wherein the Bernoulli chuck is provided with an annular gas supply port which sends gas to an outer circumferential portion side of one surface of the semiconductor wafer.

3. The apparatus for etching a semiconductor wafer according to claim 1 or 2, further comprising:
a storage bath which stores the etchant which overflows the etching bath; and circulation means which extracts the etchant in the storage bath by a pump and returns the etchant to the supply port.

4. The apparatus for etching a semiconductor wafer according to claim 1 or 2, wherein the etching bath forms an inner wall surface which spreads in the form of an inverted cone from a circumference of the supply port toward an upper end of the etching bath.

5. The apparatus for etching a semiconductor wafer according to claim 3, wherein the etching bath forms an inner wall surface which spreads in the form of an inverted cone from a circumference of the supply port toward an upper end of the etching bath.

6. An etching method for etching a semiconductor wafer by using the etching apparatus according to claims 1 or 2, comprising:
adjusting at least either a set height of the surface of the semiconductor wafer to be etched or a supply amount of the etchant supplied from the supply port; and
bringing the etchant into contact with a prescribed position of an outer circumferential portion of the semiconductor wafer.

7. An etching method for etching a semiconductor wafer by using the etching apparatus according to claim 3, comprising:
adjusting at least either a set height of the surface of the semiconductor wafer to be etched or a supply amount of the etchant supplied from the supply port; and
bringing the etchant into contact with a prescribed position of an outer circumferential portion of the semiconductor wafer.

8. An etching method for etching a semiconductor wafer by using the etching apparatus according to claim 4, comprising:
adjusting at least either a set height of the surface of the semiconductor wafer to be etched or a supply amount of the etchant supplied from the supply port; and
bringing the etchant into contact with a prescribed position of an outer circumferential portion of the semiconductor wafer.

9. An etching method for etching a semiconductor wafer by using the etching apparatus according to claim 5, comprising:
adjusting at least either a set height of the surface of the semiconductor wafer to be etched or a supply amount of the etchant supplied from the supply port; and
bringing the etchant into contact with a prescribed position of an outer circumferential portion of the semiconductor wafer.
